(19) United States
(12) Patent Application Publication
(10) Pub. No.: US 2024/0275130 A1
(43) Pub. Date: Aug. 15, 2024

(54) LASER DIODE ARRANGEMENT, METHOD OF OPERATING A LASER DIODE AND SCANNING MICROSCOPE DEVICE COMPRISING A LASER DIODE

(71) Applicant: Nearfield Instruments B.V., Rotterdam (NL)

(72) Inventors: Taras PISKUNOV, Schiedam (NL); Hamed SADEGHIAN MARNANI, Rotterdam (NL); Arseniy KALININ, Rotterdam (NL); Kevin Henri Louis MAKLES, Rotterdam (NL); Maarten Eduard VAN REIJZEN, Rotterdam (NL)

(21) Appl. No.: 18/567,881

(22) PCT Filed: Jul. 8, 2022
(86) PCT No.: PCT/NL2022/050396

§ 371 Date: Dec. 7, 2023

(30) Foreign Application Priority Data
Jul. 9, 2021 (NL) 2028674

(51) Int. Cl. H01S 5/0683; G01Q 20/02; H01S 5/042; H01S 5/068

(52) U.S. Cl. CPC H01S 5/06835; G01Q 20/02; H01S 5/042; H01S 5/06804; H01S 5/06808

(57) ABSTRACT

A laser diode arrangement is provided that comprises a laser diode, a driver (EPS) to provide an AC-electric power to the laser diode, a first feedback component (FB1) and a second feedback component (FB2). The first feedback component (FB1) is configured to sense an optical output of the laser diode and comprises an optical power control module (OPCM) to control a first waveform characteristic of the AC-electric power to maintain the sensed optical output (PM) close to a first desired value (PD). The second feedback component (FB2) is configured to estimate a temperature (TEST) of the laser diode by sensing a voltage-current characteristic of the laser diode and comprises a temperature control module (TCM) that is configured to control a second waveform characteristic of the AC-electric power, different from the first waveform characteristic to maintain the estimated temperature (TEST) close to a second desired value (TOPT).

### FIELD

The present application pertains to a laser diode arrangement.

The present application further pertains to a method of operating a laser diode. The present application still further pertains to a scanning microscope device comprising a laser diode.

### BACKGROUND

Laser diodes have a wide range of uses. An example thereof is its use in scanning probe microscopy (SPM) devices. In SPM devices a probe at a flexible carrier is scanned along a surface of a sample. A deflection of an optical beam from a laser diode at the flexible carrier is detected and the detection signal is analyzed to determine properties of the sample. It is essential therein that the optical beam rendered by the laser diode is as stable as possible, in order to minimize noise in the detection signal. Other uses include fiber optic communications, barcode readers, laser pointers, CD/DVD/Blu-ray disc reading/recording, laser printing, laser scanning, light beam illumination, which also require a stable beam.

In particular for its use in SPM devices, a high beam pointing stability is required, in other words the angular fluctuations of the beam should be small.

### SUMMARY

It is a first object of the present disclosure to provide an improved laser diode arrangement that mitigates angular fluctuations of the rendered laser beam.

It is a second object of the present disclosure to provide an improved method of operating a laser diode that mitigates angular fluctuations of the rendered laser beam.

It is a third object of the invention to provide a scanning microscope device comprising an improved laser diode.

In accordance with the first object, a laser diode arrangement is provided that comprises a laser diode, a driver, a first feedback component, and a second feedback component. Therein the driver is configured to provide an AC-electric power to the laser diode with a first waveform characteristic and a second controlled waveform characteristic different from the first waveform characteristic.

The first feedback component is configured to sense an optical output of the laser diode and comprises an optical power control module that is configured to control the first waveform characteristic to maintain the sensed optical output power close to the first desired value.

The second feedback component is configured to estimate a temperature of the laser diode by sensing a voltage-current characteristic of the laser diode and comprises a temperature control module that is configured to control the second waveform characteristic to maintain the estimated temperature close to the second desired value.

By estimating the temperature of the laser diode from a sensed voltage-current characteristic material cost is minimized. A separate temperature sensor is superfluous, and also additional connections to such a sensor are avoided. Instead the second feedback component can directly sense the voltage over the laser diode and the current conducted therethrough. In one example the second feedback component comprises a lookup table (LUT) having a plurality of addressable entries each for a respective pair of a voltage range and a current range and comprising an indication of a temperature value of the laser diode associated with said each pair of voltage range and current range. In another example a temperature value is estimated using an approximate polynomial relationship specifying the temperature as a function of the measured voltage and current. In again another example the temperature is estimated using an analytical expression specifying the temperature as a function of the voltage and the current.

Due to the fact that the feedback components each control a respective one of the waveform characteristics, both the optical output power and an operating temperature with which stable operation is achieved can be maintained.

In one embodiment, the first waveform characteristic to be controlled by the optical power control module of the first feedback component is an amplitude of the electric power parameter and the second waveform characteristic to be controlled by the temperature control module of the second feedback component is a duty cycle. Therewith the optical power control module is configured to control a change in amplitude having a sign equal to a sign of a difference between the first desired value and the sensed optical output and the temperature control module is configured to control a change in duty cycle having a sign equal to a sign of a difference between the second desired value and the estimated temperature.

In an alternative embodiment the first waveform characteristic to be controlled by the optical power control module of the first feedback component is a duty cycle of the electric power parameter, and the second waveform characteristic to be controlled by the temperature control module of the second feedback component is an amplitude. In operation the optical power control module is configured to control a change in duty cycle having a sign equal to a sign of a difference between the first desired value (P_{D}) and the temperature control module is configured to control a change in amplitude having a sign reverse to a sign of a difference between the second desired value and the estimated temperature.

In some examples, the amplitude to be controlled is the amplitude of a current supplied to the laser diode. The voltage over the laser diode is in that case a dependent parameter and is approximately proportional to the logarithm of the supplied current. In another embodiment the amplitude to be controlled is the amplitude of a voltage supplied to the laser diode. In that case the current conducted by the laser diode is a dependent parameter and is approximately proportional with the exponential of the supplied voltage. Of these embodiments a direct control of the supply current has the advantage that a setpoint can be more easily stabilized.

In some examples, a laser diode arrangement as disclosed herein further comprises an optimal temperature computation module that is configured to compute as the second desired value an optimal junction temperature with which the laser diode can generate output with an output power equal to the first desired value. In some applications a different optical output power may be required depending on the circumstances of the case. In practice, the optimal temperature for which pointing stability is maximized depends on the optical output power to be delivered.

In one embodiment the waveform with which the electric power is applied is a square wave. This is advantageous, in that it can be realized with relatively simple power control components, i.e. a controllable voltage or current source to control an amplitude of the square wave, and a pulse width modulator to modulate a pulse width with which the electric power is supplied can be realized with a controlled switching element.

In another embodiment, the waveform with which the electric power is applied is a sinewave. This operational mode is favorable for operation at higher frequencies where parasitic input capacitances of the LD prevents the use of pulse-width modulation (PWM) signals.

In accordance with the second object of this disclosure a method of operating an laser diode is provided that comprises:
providing an electric power to the laser diode having first waveform characteristic and second waveform characteristics of an electric power parameter;
sensing an optical output of the laser diode;
controlling the first waveform characteristic to maintain the sensed optical output close to a first desired value;
estimating a temperature of the laser diode by sensing a voltage-current characteristic of the laser diode;
controlling the second waveform characteristic to maintain the estimated temperature close to a second desired value.

According to a third aspect of the present disclosure, a scanning probe microscopy (SPM) device is provided that comprises:
a probe with a tip to be scanned over a surface of a sample;
a signal generator to generate an input signal to induce an acoustic signal in the probe, the tip or the sample;
an embodiment of an laser diode arrangement as specified above, to generate an optical beam to be directed to the probe resulting in secondary beam reflected by the probe;
an optical detector to provide an output signal indicative for a direction of the secondary beam;
a signal analysis module to provide an output signal indicative for features of the sample based on the input signal and the output signal.

An implementation of an SPM device may be contemplated wherein the optical detector of the SPM device serves to sense the optical output power of the laser diode, for example by using the sum of the responses of the 4 quadrants of the detector. In practice however, in most applications such measurement method will not be precise, as it is affected by the cantilever movement, speckle interference, and the light propagation medium. For example, in some applications, the SPM cantilever and sample are immersed in liquid. For this reason, it is generally preferred that a dedicated optical output power sensor is provided near the laser diode. Typically, a laser diode is provided in a package with such a sensor.

### BRIEF DESCRIPTION OF THE DRAWINGS

These and other aspects are described in more detail with reference to the drawing. Therein:

FIG. 1 schematically shows a first embodiment of a laser diode arrangement;

FIG. 2 schematically shows a second embodiment of a laser diode arrangement;

FIG. 3 schematically shows a third embodiment of a laser diode arrangement;

FIG. 4 schematically shows a fourth embodiment of a laser diode arrangement;

FIG. 5 schematically shows a fifth embodiment of a laser diode arrangement;

FIG. 6 schematically shows a sixth embodiment of a laser diode arrangement;

FIG. 7 schematically shows a scanning probe microscopy (SPM) device;

FIG. 8 shows measurement result obtained with a controllably driven laser diode.

### DETAILED DESCRIPTION OF EMBODIMENTS

Like reference symbols in the various drawings indicate like elements unless otherwise indicated.

In the following detailed description numerous specific details are set forth in order to provide a thorough understanding of the present invention. However, it will be understood by one skilled in the art that the present invention may be practiced without these specific details. In other instances, well known methods, procedures, and components have not been described in detail so as not to obscure aspects of the present invention.

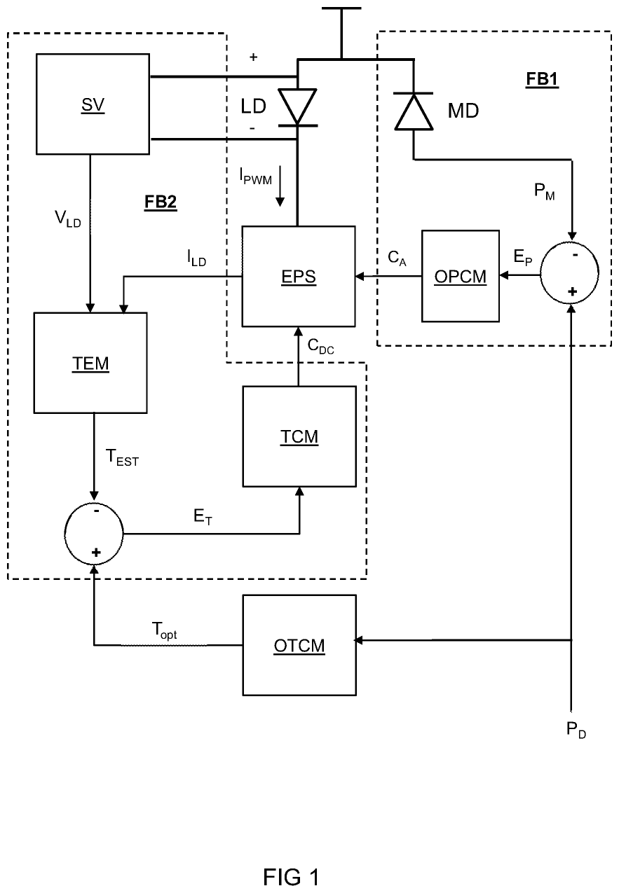

FIG. 1 schematically shows a laser diode arrangement. The arrangement comprises a laser diode LD that is connected to a driver EPS that is configured to provide an AC-electric power to the laser diode with a first controlled waveform characteristic and a second controlled waveform characteristic, different from the first controlled waveform characteristic of an electric power parameter. The arrangement further comprises a first feedback component FB1 and a second feedback component FB2.

The first feedback component FB1 is configured to sense an optical output of the laser diode and it comprises an optical power control module OPCM to control the first waveform characteristic to maintain the sensed optical output P_{M} close to a first desired value P_{D}. In the example shown, the first feedback component FB1 comprises a monitor diode MD arranged in the proximity of the laser diode LD, for example accommodated with the LD in a common package. A subtraction element, such as a differential amplifier, determines a difference E_{P} between a first desired value P_{D} and the sensed optical output P_{M} which is provided as input to the optical power control module OPCM. In response the latter provides a control signal C_{A} to control the first waveform characteristic of the electric power parameter with which the driver EPS provide the AC-electric power to the laser diode. The first desired value P_{D} is for example set by an operator, or by a main controller.

The second feedback component FB2 is configured to estimate a temperature T_{EST} of the laser diode by sensing a voltage-current characteristic of the laser diode and it comprises a temperature control module TCM configured to control the second waveform characteristic to maintain the estimated temperature T_{EST} close to a second desired value T_{OPT}. In the embodiment shown, the second feedback component FB2 comprises a voltage sensor SV that senses a voltage drop over the laser diode LD and it provides an output signal V_{LD} indicative for the sensed value to a temperature estimation module TEM. In addition, the driver EPS provides an output signal I_{LD} to the temperature estimation module TEM that is indicative for a current supplied to the laser diode LD. In some examples the output signal V_{LD} and the output signal I_{LD} respectively indicate the instantaneous voltage over the laser diode LD and the instantaneous current through the laser diode LD respectively. In other examples the output signal V_{LD} and the output signal I_{LD} indicate the respective peak values or the respective average values for example. The temperature estimation module TEM estimates the actual junction temperature of the laser diode LD based on the sensed voltage-current characteristic as indicated by the output signal V_{LD} and the output signal I_{L}. In response thereto it outputs a temperature indication signal T_{EST} indicative for the estimated temperature value. In the example shown the temperature estimation module TEM comprises a lookup table having a plurality of addressable entries each for a respective pair of a voltage range and a current range and comprising an indication of a temperature value of the laser diode associated with said each pair of voltage range and current range.

A subtraction element, such as a differential amplifier, determines a difference E_{T} between a second desired value, being a value for the junction temperature with which a stable operation is achieved as indicated by a signal T_{OPT} and the estimated temperature as indicated by the signal T_{EST}. In the example shown, an optimal temperature computation module OTCM is provided that is configured to compute as the second desired value T_{OPT} an optimal junction temperature with which the laser diode can generate an optical output with an output power equal to the first desired value P_{D}. In an alternative embodiment, for example in cases where the output power is only selectable within a relatively narrow range, a fixed value is specified for the second desired value T_{OPT}.

In the embodiment of FIG. 1, the controlled electric power parameter is a current supplied to the laser diode LD. The first waveform characteristic to be controlled by the optical power control module OPCM of the first feedback component FB1 is an amplitude of the supplied current. In operation, the optical power control module OPCM controls a change in amplitude having a sign equal to a sign of a difference E_{P} between the first desired value P_{D} and the sensed optical output P_{M}. If for example the desired optical output power Po exceeds the sensed optical output P_{M} it causes the driver EPS to provide the current with an increased amplitude.

The second waveform characteristic that is to be controlled by the temperature control module TCM of the second feedback component FB2 is a duty cycle with which the current I_{PWM} is supplied. In operation the temperature control module TCM controls a change in duty cycle having a sign equal to a sign of a difference E_{T} between the second desired value T_{OPT} and the estimated temperature T_{EST}. For example, if the estimated temperature T_{EST} is higher than the second desired value T_{OPT}, a sign of a difference E_{T} is negative and the temperature control module TCM decreases the duty cycle. As such this would imply a decrease in optical output power, but typically the first feedback component FB1 can achieve a correction in optical power relatively fast, as compared to changes caused by duty cycle variations for the purpose of temperature variations. This is because the junction temperature is related to the integral of the power dissipated therein, and the optical output power is directly related to the supplied electric power. Nevertheless, if desired, the response speed of the first feedback component FB1 and the second feedback component FB2 may be appropriately configured. For example, the first feedback component FB1 may be a proportional derivative (PD) controller with an additional differentiating component D to a proportional component P for a faster response and/or the second feedback component FB2 may be a proportional integrating (PI) controller with an additional integrating component I to a proportional component P for a slower response.

It is further noted that the laser diode arrangement may include a feedforward control module that specifies a respective reference value for the amplitude and the duty cycle based on a prior estimation. In that case the first feedback component FB1 and the second feedback component FB2 specify respective adaptations to the respective reference values to achieve that the desired operational temperature and the desired optical power are approximated.

In the embodiment shown in FIG. 1, the amplitude to be controlled is the amplitude of a current supplied to the laser diode LD. The voltage over the laser diode is in that case a dependent parameter and is approximately proportional to the logarithm of the supplied current in accordance with the response characteristic of the laser diode.

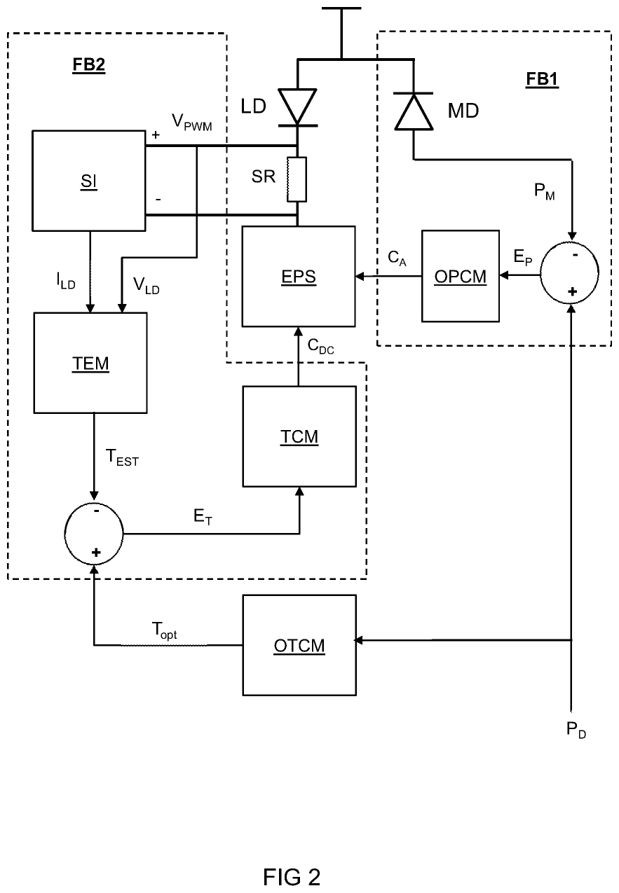

FIG. 2 shows another embodiment, that corresponds the embodiment of FIG. 1, apart from the fact that the amplitude to be controlled is the amplitude of a voltage supplied to the laser diode. In this case the output signal C_{A} of the optical power control module OPCM specifies the amplitude of a pulse width modulated voltage V_{PWM} to be supplied to the laser diode LD by the driver EPS.

In that case the current conducted by the laser diode LD is a dependent parameter and is approximately proportional with the exponential of the supplied voltage. Of these embodiments a direct control of the supply current has the advantage that a setpoint can be more easily stabilized.

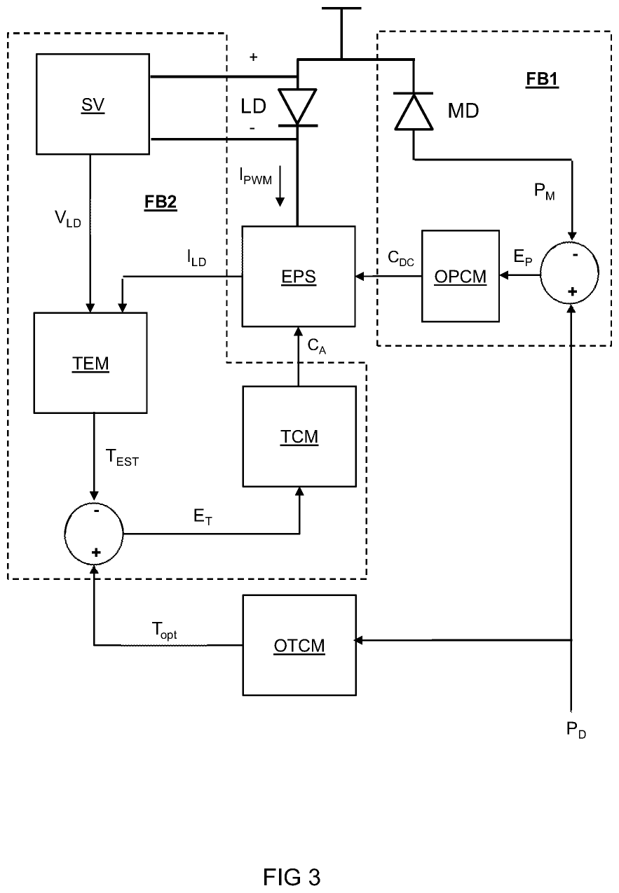

FIG. 3 shows a still further embodiment. As in the embodiment of FIG. 1, the driver EPS provide a controlled pulse width modulated current I_{PWM} to the laser diode LD. However, in this case the optical power control module OPCM of the first feedback component FB1 controls the duty cycle of the current, and the second feedback component FB2 controls the amplitude of the current.

In operation, the optical power control module OPCM controls a change in duty cycle having a sign equal to a sign of a difference E_{P} between the first desired value P_{D} and the sensed optical output P_{M}. For example, if the sensed optical output P_{M} is less than the first desired value P_{D}, the sign of the difference E_{P} is positive and the optical power control module OPCM controls a positive change in duty cycle.

In operation the temperature control module TCM controls a change in amplitude having a sign reverse to a sign of a difference E_{T} between the second desired value T_{OPT} and the estimated temperature T_{EST}. For example, if the estimated temperature T_{EST} is below the second desired value T_{OPT} and the sign of the difference E_{T} is positive and the temperature control module TCM controls the driver EPS to provide the pulse width modulated current I_{PWM} with a lower amplitude. In the absence of the first feedback component FB1 the junction temperature would even drop further below the desired value T_{OPT}, and also the output power would drop, however due to the relatively fast response of the optical power control module OPCM, the duty cycle increases to maintain the specified output power so that by the combined effect of the first feedback component FB1 and the second feedback component FB2 a setpoint is achieved with a lower amplitude and a larger duty cycle resulting in an increased junction temperature that better approaches the second desired value T_{OPT}.

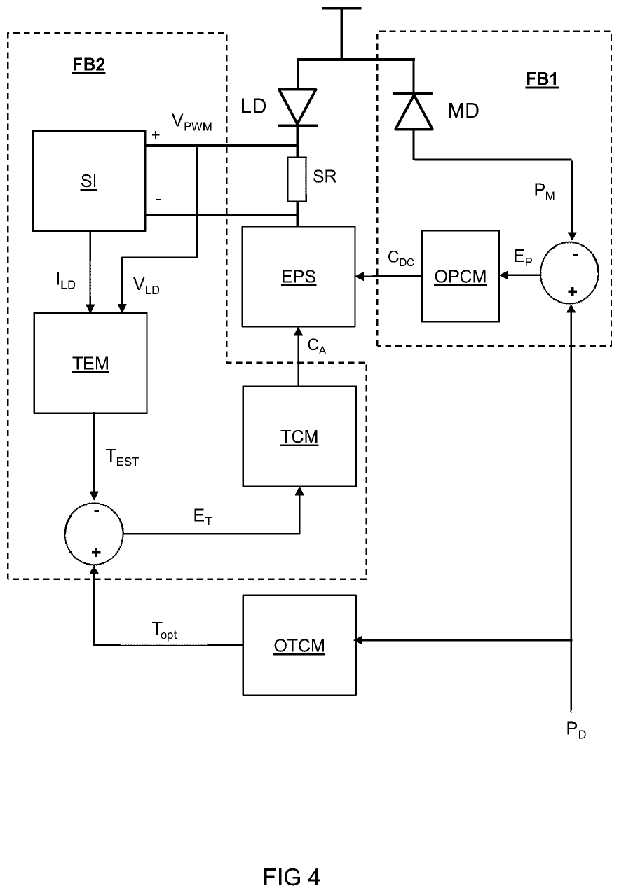

FIG. 4 shows another embodiment, that corresponds the embodiment of FIG. 3, apart from the fact that the amplitude to be controlled is the amplitude of a voltage supplied to the laser diode LD.

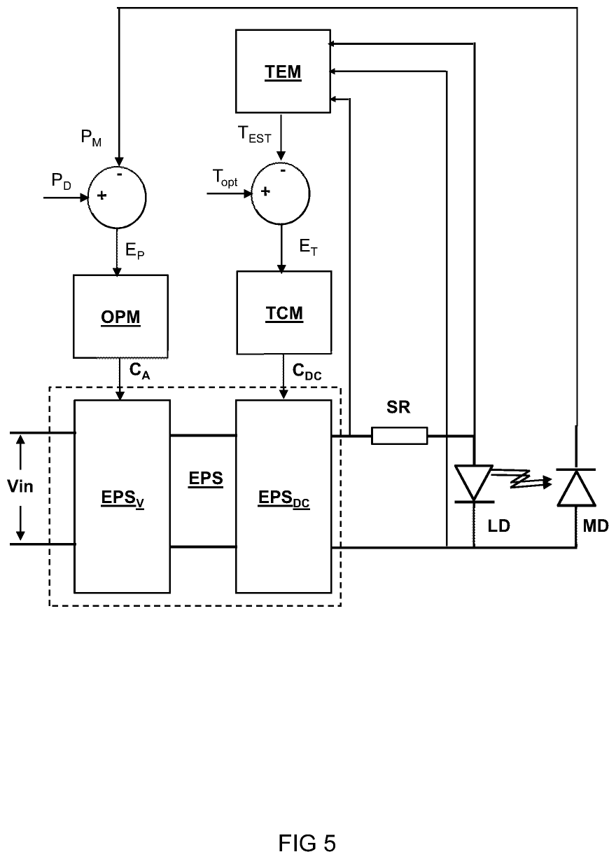

A further elaboration of the embodiment of FIG. 2 is illustrated in FIG. 5. As shown therein the driver EPS comprises a controllable voltage supply module EPS_{V} and a controllable pulse width modulator module EPS_{DC}. The controllable voltage supply module EPS_{V} receives an input voltage V_{IN} from an external power supply such as a battery and provides a controlled voltage in accordance with amplitude control signal C_{A} to the controllable pulse width modulator module EPS_{DC}. The controllable pulse width modulator module EPS_{DC} provides in response thereto the controlled voltage with a duty cycle specified by the duty cycle control signal C_{DC} to the laser diode LD. It is noted that due to the presence of the sense resistor SR the amplitude of the voltage over the laser diode LD is slightly smaller than the amplitude as provided by the driver EPS. In practice this is not a problem as the two feedback components FB1, FB2 will anyhow tend to control the driver EPS so that the desired operational temperature and desired optical power are achieved.

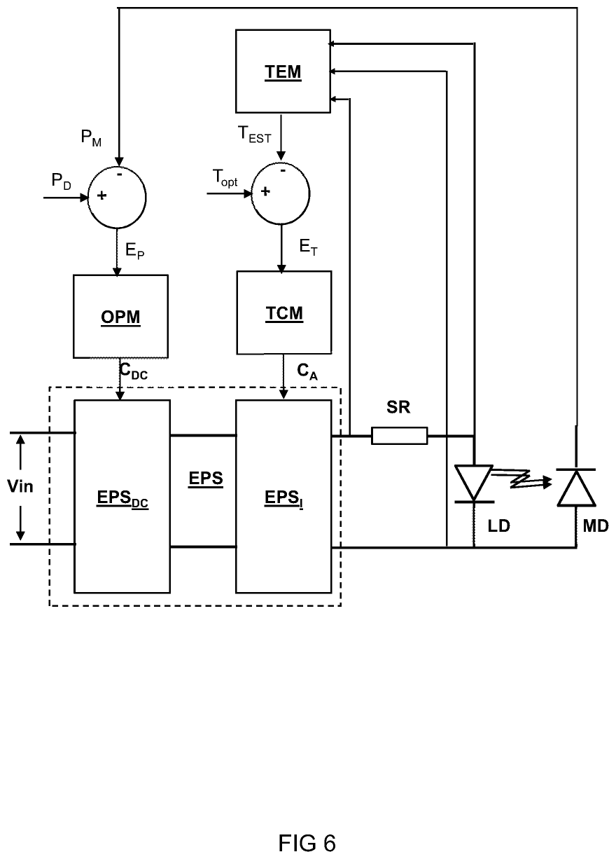

A further elaboration of the embodiment of FIG. 3 is illustrated in FIG. 6. As shown therein the driver EPS comprises a controllable pulse width modulator module EPS_{DC} and a controllable current supply module EPS_{I}. The controllable pulse width modulator module EPS_{DC} receives an input voltage V_{IN} from an external power supply such as a battery and provides a controlled pulse width modulated supply voltage with a duty cycle specified by the duty cycle control signal C_{DC} to the controllable current supply module EPS_{I}. The controllable current supply module EPS_{I} then provides a current with an amplitude controlled by amplitude control signal C_{A} and pulse width modulated by the pulse width modulator module EPS_{DC} to the laser diode LD.

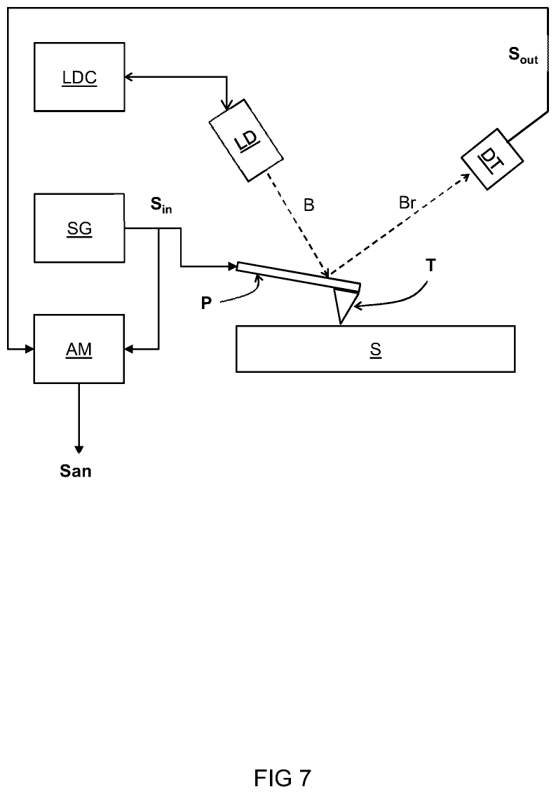

FIG. 7 schematically shows a scanning probe microscopy (SPM) device that comprises a probe P, a signal generator SG, an optical laser diode arrangement LDC, LD, an optical detector DT and a signal analysis module AM. The optical laser diode arrangement is for example one of the embodiments as shown in FIGS. 1-6. Therein the controlled laser driver LDC is the combination of driver EPS, first feedback component FB1 and second feedback component FB2. The interconnection between the block LDC and the laser diode LD represent the power supply lines to the laser diode LD and an output from an optical sensor MD integrated with the laser diode in a common package. Separate temperature sensor lines are superfluous as the second feedback component FB2 is configured to estimate the junction temperature from the voltage-current characteristic of the laser diode LD.

In the SPM device, the probe P has a tip T to be scanned over a surface of a sample S. The tip T is for example provided at a cantilever, a membrane or other flexible carrier. The signal generator SG is provided to generate an input signal Sin to induce an acoustic signal in the probe P, the tip T or the sample S. The laser diode is configured to generate a stable optical beam B directed to the probe P. This results in a secondary beam Br reflected by the probe and sensed by an optical detector DT such as a quadrant detector. In response thereto the optical detector DT provides an output signal Sout indicative for a direction of the secondary beam Br. As the secondary beam results from a reflection of the original beam B on the probe, the sensed direction is indicative for a deformation of the probe which in turn is indicative for on-surface or sub-surface features of the sample. In accordance therewith, the signal analysis module AM provide an output signal San that is indicative for the features of the sample S based on the input signal Sin and the output signal Sout. Due to the fact that the controlled laser driver LDC drives the laser LD such that it generates a stable output beam B with a controlled power, it is achieved that noise in the output signal Sout is minimized.

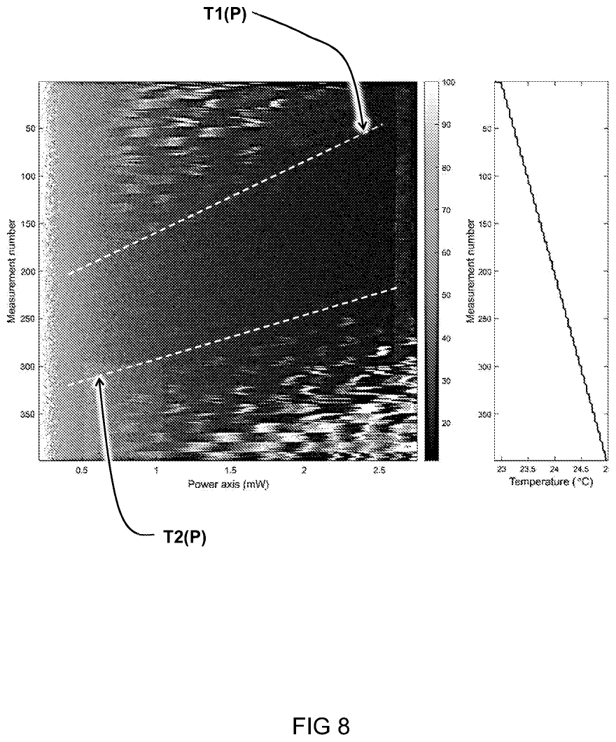

FIG. 8 shows results obtained from a series of 400 measurements performed with a HL6320G TO-9 laser diode. For the purpose of the experiment the temperature of the laser diode was stepwise increased with 400 steps of 0.005° C. in a range from 23 to 25° C. In each of the 400 measurements, the output power was swept from 0.2 mW to 2.7 mW. A quadcell was used to measure the noise level of the laser diode for each combination of temperature and output power.

The left part of FIG. 8 shows the measured noise level in arbitrary units. The vertical axis indicates the measurement number and the horizontal axis indicates the output power in mW. The brightness is indicative for the measured noise level. The right part of FIG. 8 shows the temperature set for each of the measurements on the horizontal axis and the measurement number on the vertical axis. It can be seen that in case of operation at a low output power, e.g., less than 0.3 mW it is difficult to reduce position noise. However, above this output power level, noise can be minimized by appropriately controlling the junction temperature. For example, for an output power of 1.0 mW, the temperature should be maintained within a range of about 23.8° C. to about 24.5° C. For an output power of 2.5 mW, the temperature should be maintained within a range of about 23.3° C. to about 24.1° C.

While the present invention has been described with respect to a limited number of embodiments, those skilled in the art will appreciate numerous modifications and variations therefrom within the scope of this present invention as determined by the appended claims. In the claims the word “comprising” does not exclude other elements or steps, and the indefinite article “a” or “an” does not exclude a plurality. A single component or other unit may fulfill the functions of several items recited in the claims. The mere fact that certain measures are recited in mutually different claims does not indicate that a combination of these measures cannot be used to advantage. Any reference signs in the claims should not be construed as limiting the scope.

1. An optical laser diode arrangement comprising:
a laser diode;
a driver to provide an AC-electric power to the laser diode with a first controlled waveform characteristic and a second controlled waveform characteristic of an electric power parameter, the second controlled waveform characteristic being different from the first controlled waveform characteristic;
a first feedback component configured to sense an optical output of the laser diode and comprising an optical power control module to control the first waveform characteristic to maintain the sensed optical output close to a first desired value; and
a second feedback component configured to estimate a temperature of the laser diode by sensing a voltage-current characteristic of the laser diode and comprising a temperature control module configured to control the second waveform characteristic to maintain the estimated temperature close to a second desired value.

2. The optical laser diode arrangement according to claim 1,
wherein the first waveform characteristic to be controlled by the optical power control module of the first feedback component is an amplitude of the electric power parameter, the optical power control module being configured to control a change in amplitude having a sign equal to a sign of a difference between the first desired value and the sensed optical output, and
wherein the second waveform characteristic to be controlled by the temperature control module of the second feedback component is a duty cycle, the temperature control module being configured to control a change in duty cycle having a sign equal to a sign of a difference between the second desired value and the estimated temperature.

3. The optical laser diode arrangement according to claim 1,
wherein the first waveform characteristic to be controlled by the optical power control module of the first feedback component is a duty cycle of the electric power parameter, the optical power control module being configured to control a change in duty cycle having a sign equal to a sign of a difference between the first desired value and the sensed optical output,
wherein the second waveform characteristic to be controlled by the temperature control module of the second feedback component is an amplitude, and
wherein the temperature control module is configured to control a change in amplitude having a sign reverse to a sign of a difference between the second desired value and the estimated temperature.

4. The optical laser diode arrangement according to claim 2, wherein the amplitude to be controlled is an amplitude of a current supplied to the laser diode.

5. The optical laser diode arrangement according to claim 2, wherein the amplitude to be controlled is an amplitude of a voltage supplied to the laser diode.

6. The optical laser diode arrangement according to claim 1, further comprising an optimal temperature computation module that is configured to compute as the second desired value an optimal junction temperature with which the laser diode can generate an optical output with an output power equal to the first desired value.

7. A method of operating an optical laser diode, comprising:
providing an AC-electric power to the laser diode with a first controlled waveform characteristic and a second controlled waveform characteristic of an electric power parameter, the second controlled waveform characteristic being different from the first controlled waveform characteristic;
sensing an optical output power of the laser diode;
controlling the first waveform characteristic to maintain the sensed optical output close to a first desired value;
estimating a temperature of the laser diode by sensing a voltage-current characteristic of the laser diode; and
controlling the second waveform characteristic to maintain the estimated temperature close to a second desired value.

8. The method according to claim 7,
wherein the first controlled waveform characteristic is an amplitude of the electric power parameter, wherein a controlled change of the amplitude has a sign equal to a sign of a difference between the first desired value and the sensed optical output, and
wherein the second controlled waveform characteristic is a duty cycle, wherein a controlled change in duty cycle has a sign equal to a sign of a difference between the second desired value and the estimated temperature.

9. The method according to claim 8,
wherein the first controlled waveform characteristic is a duty cycle of the electric power parameter, wherein a controlled change in duty cycle has a sign equal to a sign of a difference between the first desired value and the sensed optical output, and
wherein the second controlled waveform characteristic is an amplitude, wherein a controlled change in amplitude has a sign reverse to a sign of a difference between the second desired value and the estimated temperature.

10. The method according to claim 8, wherein the amplitude to be controlled is an amplitude of a current supplied to the laser diode.

11. The method according to claim 8, wherein the amplitude to be controlled is an amplitude of a voltage supplied to the laser diode.

12. The method according to claim 7, further comprising computing as the second desired value an optimal junction temperature with which the laser diode can generate an optical output with an output power equal to the first desired value.

13. A scanning probe microscopy device comprising:
a probe with a tip to be scanned over a surface of a sample;
a signal generator to generate an input signal to induce an acoustic signal in the probe, the tip or the sample;
a laser diode arrangement as claimed in either of the clams 1-6 to generate an optical beam to be directed to the probe resulting in a secondary beam reflected by the probe;
a optical detector to provide an output signal indicative for a direction of the secondary beam;
a signal analysis module to provide an output signal indicative for features of the sample based on the input signal and the output signal,
wherein the laser diode arrangement comprises:
a laser diode;
a driver to provide an AC-electric power to the laser diode with a first controlled waveform characteristic and a second controlled waveform characteristic of an electric power parameter, the second controlled waveform characteristic being different from the first controlled waveform characteristic;
a first feedback component configured to sense an optical output of the laser diode and comprising an optical power control module to control the first waveform characteristic to maintain the sensed optical output close to a first desired value; and
a second feedback component configured to estimate a temperature of the laser diode by sensing a voltage-current characteristic of the laser diode and comprising a temperature control module configured to control the second waveform characteristic to maintain the estimated temperature close to a second desired value.

14. The scanning probe microscopy device according to claim 13,
wherein the first waveform characteristic to be controlled by the optical power control module of the first feedback component is an amplitude of the electric power parameter, the optical power control module being configured to control a change in amplitude having a sign equal to a sign of a difference between the first desired value and the sensed optical output, and
wherein the second waveform characteristic to be controlled by the temperature control module of the second feedback component is a duty cycle, the temperature control module being configured to control a change in duty cycle having a sign equal to a sign of a difference between the second desired value and the estimated temperature.

15. The scanning probe microscopy device according to claim 13,
wherein the first waveform characteristic to be controlled by the optical power control module of the first feedback component is a duty cycle of the electric power parameter, the optical power control module being configured to control a change in duty cycle having a sign equal to a sign of a difference between the first desired value and the sensed optical output, and
wherein the second waveform characteristic to be controlled by the temperature control module of the second feedback component is an amplitude, the temperature control module being configured to control a change in amplitude having a sign reverse to a sign of a difference between the second desired value and the estimated temperature.

16. The scanning probe microscopy device according to claim 14, wherein the amplitude to be controlled is an amplitude of a current supplied to the laser diode.

17. The scanning probe microscopy device according to claim 15, wherein the amplitude to be controlled is an amplitude of a current supplied to the laser diode.

18. The scanning probe microscopy device according to claim 14, wherein the amplitude to be controlled is an amplitude of a voltage supplied to the laser diode.

19. The scanning probe microscopy device according to claim 15, wherein the amplitude to be controlled is an amplitude of a voltage supplied to the laser diode.

20. The scanning probe microscopy device according to claim 13, further comprising an optimal temperature computation module that is configured to compute as the second desired value an optimal junction temperature with which the laser diode can generate an optical output with an output power equal to the first desired value.
